(19) United States
(12) Patent Application Publication
(10) Pub. No.: US 2005/0275565 A1
(43) Pub. Date: Dec. 15, 2005

(54) Magnetizable polymeric compositions

(76) Inventors: Daniel Nachtigal, Ann Arbor, MI (US); Craig A. Chmielewski, Shelby Township, MI (US)

Correspondence Address: FREUDENBERG-NOK GENERAL PARTNERSHIP;LEGAL DEPARTMENT, 47690 EAST ANCHOR COURT, PLYMOUTH, MI, 48170-2455, US

(21) Appl. No.: 10/424,642

(22) Filed: Apr. 28, 2003

Related U.S. Application Data
(60) Provisional application No. 60/442,572, filed on Jan. 23, 2003.

(51) Int. Cl. H03M 1/22

(52) U.S. Cl. 341/16

(57) ABSTRACT

A magnetizable composition comprises a phase made of a thermoplastic polymer material, a second phase containing a cured elastomeric material, and a hard magnetic material dispersed in both the thermoplastic and the elastomeric phases. The phases are blended into a homogenous mixture suitable for use in fabricating shaped articles. The shaped articles may be magnetized to create alternating opposite poles along the surface of the article, to provide articles useful as encoders and targets for measuring rotational position or speed.

### CROSS-REFERENCE TO RELATED APPLICATIONS

This application claims priority from U.S. Provisional Application No. 60/442,572, filed Jan. 23, 2003.

### FIELD OF THE INVENTION

This invention relates in general to magnetizable thermoplastic elastomers, and to the application of such elastomers for use with magnetic speed sensor targets (encoders).

### BACKGROUND OF THE INVENTION

Rotational speed sensors such as those used in automotive applications have generally been based on principles of magnetic field sensing. Targets for speed sensors, such as magnetic encoders, generally have a magnetizable substance bonded to a structural support ring, wherein alternating magnetic poles are produced around the circumference of the magnetizable, substance. Thermoset elastomers have been used as carrier for ferrite powder in the magnetizable substance, as they provides adequate mechanical, dynamic and thermal behavior needed in the press-fit conditions common in automotive wheel-speed applications. However, thermoset elastomer-based magnetic compounds are difficult to blend in production-sized rubber compounding equipment due to the high density and loading levels of ferrite in the compound. For example, production batch volumes weigh two to four times more than standard rubber compound batches, making handling the material difficult. In addition, processing thermoset elastomer-based magnetic compounds requires relatively expensive equipment and can be slow and laborious due to the curing process.

Thermoplastic elastomers are a potential replacement for thermoset rubbers in magnetizable compounds for encoders, but insufficient material properties and durability limit their potential use. An encoder employed in an automotive application may have an operating temperature range of −40 degrees C. to 125 degree C. Commercially available thermoplastic elastomers, when loaded with magnetizable ferrite, lose their elongation and consequently their durability in extreme thermal conditions. Thermoplastic elastomer based magnetic encoders that include loadings of about fifty percent strontium ferrite can perform under certain environmental conditions, but are generally more brittle than is desired for this type of application, especially in comparison to encoders.

The use of engineered thermoplastics as carriers for the magnetic ferrite in order to produce magnetic materials has met limited success. To attain highly magnetizable compounds useful for magnetic speed-sensor targets, volumetric loading of ferrite in the compound generally must exceed twenty five percent. At these loadings, engineered thermoplastics become very brittle, leading to material handling difficulties. Moreover, the engineered thermoplastics do not meet the high levels of static, dynamic and thermal durability that magnetic encoders require. Material expansion and contraction due to thermal conditions often leads to stress cracking of engineering resin-based magnetic materials—particularly a problem when the magnetic compound is mated to a support member with a dissimilar thermal expansion coefficient. Such mating structure materials may include, for example, stainless steel or sintered iron. Consequently, an engineered thermoplastic loaded with high amounts of ferrite powder and still capable of withstanding the elevated temperatures and other environmental conditions required for magnetic encoders, through continuous operation for weeks at a time, has not yet to be found.

Thus, it is desirable to have a material that is suitable for use as a magnetic encoder, with the high ferrite loadings, and which maintains the desired material properties, while still maintaining an case of fabrication of components.

### SUMMARY OF THE INVENTION

A magnetizable thermoplastic elastomer composition comprises a phase made of a thermoplastic polymer material, a second phase containing a cured elastomeric material, and a hard magnetic material dispersed in both the thermoplastic and the elastomeric phases. The phases are blended into a homogenous mixture suitable for use in fabricating shaped articles. The shaped articles may be magnetized to create alternating opposite poles along the surface of the article.

The invention also provides an encoder comprising an encoder case and an encoder elastomer adhered to the case, wherein the encoder elastomer has the two-phase structure described above. The encoder may be configured as a target wheel in a rotational speed sensor operating on magnetic principles. In this embodiment, the encoder elastomer is magnetized to provide alternating opposite magnetic poles along the surface of the target wheel. The target wheel is adjacent to a magnetic sensor and movable relative to the sensor.

The process of making the compositions of the invention, in which magnetic material is incorporated into a blend of thermoplastic material and elastomeric material prior to curing the elastomer, allows using both thermoplastic and thermo set phases of the blended material as carriers for the magnetic materials. This allows for higher volume matrix loadings of the magnetic material while still maintaining desired material properties.

An advantage of the present invention is that the magnetizable compositions combine the mechanical and environmental durability advantages of thermoset elastomer based magnetic compounds under the range of environmental conditions needed for vehicle encoder applications with the ease of processing and manufacturing offered by engineered thermoplastics. In a preferred embodiment, the invention incorporates high temperature clastomers such as AEM or ACM rubbers at desired amounts, so that even at the high amounts of magnetic materials needed to produce encoders that are sufficiently magnetizable, the material is strong and flexible enough to produce robust parts for handling and function.

The compositions of the invention can be melt processed in standard thermoplastic processing equipment, such as injection molders, plastic extruders and blow molders, and yet still maintain material properties needed for use in magnetic encoders. In a preferred embodiment, the material is used in magnetic encoders employed under extreme environmental conditions experienced by our motor vehicles. Shaped article made from the compositions may be magnetized according to known procedure.

Advantageously, the magnetizable thermoplastic elastomers can readily be produced by a continuous compounding operation such as twin screw extrusion. The product of extrusion can be cut into small pellets for ease of handling and fabricating into components using inexpensive thermoplastic processing equipment.

### BRIEF DESCRIPTION OF THE DRAWINGS

The present invention will become more fully understood from the detailed description and the accompanying drawings, wherein:

FIG. 1 is a cross sectional view of a seal and encoder installed in a bearing.

FIG. 2 is a plan view of an embodiment of a sensor target with a radial encoder.

FIG. 3 is a partial cross section taken along line 3-3 in FIG. 2; and

FIG. 4 is a cross sectional view of an embodiment of a sensor target.

FIG. 5 illustrates an embodiment of a method for making the compositions of the invention.

### DETAILED DESCRIPTION OF EMBODIMENTS OF THE INVENTION

Magnetizable compositions of the invention contain two homogenously blended polymeric phases wherein magnetizable particles of a hard magnetic material are dispersed in both polymeric phases. A first polymeric phase is made of a thermoplastic polymeric material, and the second polymeric phase contains a cured elastomeric polymeric material. The elastomeric polymeric material may be fully cured or partially cured.

The compositions of the invention are relatively heavily loaded with a hard magnetic material to provide compositions that can be formed into encoders and targets for rotational sensors that operate on magnetic principles. In particular, shaped articles produced from the magnetizable compositions of the invention may be magnetized according to known procedures to produce alternating opposite magnetic poles along a surface of the shaped article.

The hard magnetic material used in the invention are those materials that are ferromagnetic but retain their crystal structure once a magnetic field is applied. They are materials used to form permanent magnets. As such, they strongly resist demagnetization once they are magnetized. In general, such materials are known, and exhibit coercivities H_{c} of 10 to over 100 kA/m, where A/m represents an oersted unit. Commonly used classes of hard magnetic materials include strontium ferrite oxide, barium-ferrite oxide, Alnico ferrite, and rare-earth ferrite.

Barium-ferrite has a nominal structure of BaO.6Fe₂O₃, while strontium ferrite is given as SrO.6Fe₂O₃. Alnico ferrites are iron alloys containing aluminum, nickel and cobalt, as well as other optional metals. Specific examples include Alinico 3, Alnico 8, and Alnico 9. The listed Alnico ferrites contain about 34 to 50% iron, about 24-35% cobalt, about 15% nickel, and 7-8% aluminum, the percentages being based on the total weight of the alloy. Other hard materials include iron alloys having atomic formulas Fe₆₅Cr₃₂Co₃ and Fe₆₃Cr₂₅Col₁₂. A cobalt samarium alloy of atomic formula Co₅Sm is also available.

Elongated single domain (ESD) Fe—Co material is also available as a hard magnetic material. It is an alloy containing about 9.9% iron Fe, 5.5% Co, 77% Pb, and about 8.6% Sn, the percentages being based on the total weight of the alloy. Other known alloys having hard magnetic properties useful for formulating the magnetizable compositions of the invention include Mn—Al—C (70 wt. % Mn, 29 wt. % Al, 0.5 wt. % Ni, 0.5 wt. % C), Co—Pt (77 wt. % Pt, 23 wt. % Co) and Fe—Nd—B (66 wt. % Fe, 33 wt. % Nd, and 1 wt. % B).

To obtain sufficient magnetic strength from the magnetizable compositions of the invention, the volumetric loading of the hard magnetic materials is possible at a volume % of about 1% to 99%. However, to obtain good processability along with advantageous properties of higher material strength and durability, it is preferred to provide compositions containing about 25 volume % to about 67 volume % of the hard magnetic material.

The thermoplastic material and the cured elastomeric material are present in the magnetizable compositions of the invention at levels sufficient to provide the necessary material and strength and durability for the application, while retaining good processability on standard plastics equipment. If the level of thermoplastic material is taken as 100, the level of the cured elastomeric material can generally range from about 10 to about 300. Preferably, the elastomeric material level is at 25. In another preferred embodiment, the level of elastomeric material is at least about 50. That is, the ratio of cured elastomeric material to thermoplastic material in the compositions of the invention ranges from about 1:10 to about 3:1. In a preferred embodiment, the cured elastomeric material is present relatively to the thermoplastic material at a rate ratio of about 1:1 or less. Preferably, the ratio of elastomeric material to thermoplastic material is at least 1:4. In another preferred embodiment, the elastomeric material is present at about 50-75% that of the thermoplastic material.

In a preferred embodiment, the cured elastomeric material is present as particles dispersed in a continuous thermoplastic material phase. Thus, it is preferred to provide the elastomeric material and the thermoplastic material in such a ratio that a continuous phase of thermoplastic material is produced in the blend. No matter the structure of the elastomeric and thermoplastic phases, the hard magnetic material is evenly distributed in both phases. Incorporation of the hard magnetic material into both the cured elastomeric phase and the thermoplastic phase is accomplished by mixing the thermoplastic material, the hard magnetic material, and the elastomeric material in an uncured state for a time sufficient to disperse the magnetic material in both phases prior to a subsequent curing step, discussed further below.

In a preferred embodiment, the thermoplastic polymeric material used in the invention may be a thermoplastic elastomer (TPE). Thermoplastic elastomers have some physical properties of rubber, such as softness, flexibility and resilience, but may be processed like thermoplastics. A transition from a melt to a solid rubber-like composition occurs fairly rapidly upon cooling. The transition is readily reversible upon heating. This is in contrast to conventional elastomers, which harden slowly (and generally irreversibly) upon heating. Thermoplastic elastomers may be processed on conventional plastic equipment such as injection molders and extruders. Scrap may generally be readily recycled.

Thermoplastic elastomers have a multi-phase structure, wherein the phases are generally intimately mixed. In many cases, the phases are held together by graft or block copolymerization. At least one phase is made of a material that is hard at room temperature but fluid upon heating. Another phase is a softer material that is rubber like at room temperature. It is common to refer to the hard phase as “crystalline” and to the soft phase as “amorphous”.

Some thermoplastic elastomers have an A-B-A block copolymer structure, where A represents hard segments and B is a soft segment. Because most polymeric materials tend to be incompatible with one another, the hard and soft segments of thermoplastic elastomers tend to associate with one another to form hard and soft phases. For example, the hard segments tend to form spherical regions or domains dispersed in a continuous elastomer phase. At room temperature, the domains are hard and act as physical crosslinks tying together elastomeric chains in a 3-D network. The domains tend to lose strength when the material is heated or dissolved in a solvent.

Other thermoplastic elastomers have a repeating structure represented by (A-B)ₙ, where A represents the hard segments and B the soft segments as described above.

Many thermoplastic elastomers are known. They in general adapt either the A-B-A triblock structure or the (A-B)ₙ repeating structure. Non-limiting examples of A-B-A type thermoplastic elastomers include polystyrene/polysiloxane/polystyrene, polystyrene/polyethylene-co-butylene/polystyrene, polystyrene/polybutadiene polystyrene, polystyrene/polyisoprenelpolystyrene, poly-α-methyl styrene/polybutadiene/poly-α-methyl styrene, poly-α-methyl styrene/polyisoprene/poly-α-methyl styrene, and polyethylene/polyethylene-co-butylene/polyethylenc.

Non-limiting examples of thermoplastic elastomers having a (A-B)ₙ repeating structure include polyamide/polyether, polysulfone/polydirnethylsiloxane, polyurethane/polyester, polyurethane/polyether, polyester/polyether, polycarbonatel polydimethylsiloxane, and polycarbonate/polyether. Among the most common commercially available thermoplastic elastomers are those that contain polystyrene as the hard segment. Triblock elastomers are available with polystyrene as the hard segment and either polybutadiene, polyisoprene, or polyethylene-co-butylene as the soft segment Similarly, styrene butadiene repeating co-polymers are commercially available, as well as polystyrene/polyisoprene repeating polymers.

In a preferred embodiment, a polyester thermoplastic elastomer is used to make the magnetizable compositions of the invention. Such thermoplastic elastomers are generally (A-B)ₙtype block copolymers. In one embodiment, the hard segment is made of a polyester structure formed from diacids and low molecular weight diols such as ethylene glycol and butylene. The soft segment is made of a polyester structure based on long chain polyether glycols. Polyester TPE have some rubber like properties, but may be readily formed into parts by a variety of thermoplastic processing techniques. They exhibit good toughness, resilience, resistance to creep, impact and flex fatigue, low temperature flexibility, retention of properties at elevated temperatures, and dynamic properties. Polyester TPE are available commercially, for example from DuPont under the Hytrel® tradename.

The thermoplastic polymeric material may also be selected from among solid, generally high molecular weight, plastic materials. Preferably, the materials are crystalline or semi-crystalline polymers, and more preferably have a crystallinity of at least 25 percent as measured by differential scanning calorimetry. Polymers with a high glass transition temperature are also acceptable as the thermoplastic polymeric material. The thermoplastic also preferably has a melt temperature or glass transition temperature in the range from about 80° C. to about 350° C., but the melt temperature should generally be lower than the decomposition temperature of the thermoplastic vulcanizate.

Non-limiting examples of thermoplastic polymers include polyolefins, polyesters, nylons, polycarbonates, styrene-acrylonitrile copolymers, polyethylene terephthalate, polybutylene terephthalate, polyamides, polystyrene, polystyrene derivatives, polyphenylene oxide, polyoxymethylene, and fluorine-containing thermoplastics. Polyolefins are formed by polymerizing a-olefins such as, but not limited to, ethylene, propylene, 1-butene, 1-hexene, 1-octene, 2-methyl-1-propene, 3-methyl-1-pentene, 4-methyl-1-pentene, 5-methyl-1-hexene, and mixtures thereof. Copolymers of ethylene and propylene or ethylene or propylene with another α-olefin such as 1-butene, 1-hexene, 1-octene, 2-methyl-1-propene, 3-methyl-1-pentene, 4-methyl-1-pentene, 5methyl-1-hexene or mixtures thereof are also contemplated. These homopolymers and copolymers, and blends of them, may be incorporated as the thermoplastic polymeric material of the invention.

The cured elastomeric polymeric material of the invention is based on the product of vulcanization or cure of elastomeric material that are well known in the art. Upon cure, the elastomeric materials become rubber like in physical properties. For example, rubber like materials are characterized by high levels of resilience, softness, and compression set. Many suitable elastomeric polymeric materials are known, which can be cured or vulcanized according to known procedures, such as described in the Encyclopedia of Polymer Science and Engineering, Volume 17 in the article entitled “Vulcanization”. Preferred elastomers include those that are known to withstand high temperatures as well as provide adequate chemical resistance to fluids such as those found in automotive applications. Among preferred elastomers for use in the magnetizable compositions of the invention are acrylic elastomers and ethylene acrylic elastomers.

Acrylic elastomers have the ASTM designation ACM for polymers of ethylacrylate and other acrylates, and ANM for copolymers of ethyl or other acrylates with acrylonitrile. Acrylic elastomers are prepared by polymerizing so-called backbone monomers with optionally a minor amount of cure site monomer. The backbone monomers are selected from among ethyl acrylate and other acrylic monomers. Other preferred acrylic acrylate monomers to be co-polymerized together with ethyl acrylate to make acrylic elastomers include n-butyl acrylate, 2-methoxyethyl acrylate, and 2-ethoxyethyl acrylate.

The acrylic elastomers may contain from about 1 to about 5 mole % or weight % of cure site monomers to introduce reactive sites for subsequent crosslinking. The particular cure site monomer used in an acrylic elastomer is in general proprietary to the supplier of the elastomer. Among common cure site monomers are those that contain unsaturated carbon bonds and their side chain and those that contain a carbon chlorine bond in the side chain. Acrylic elastomers (ACM) are commercially available, such as from Zeon under the Nypol® and Hytemp® tradenames, and from Unimatec under the Noxtite® tradename.

Ethylene acrylic elastomers have the ASTM designation AEM. They are based on copolymers of ethylene and acrylate monomers, with a minor amount of cure site monomer, usually containing a carboxyl group in the side chain. Curing agents or crosslinking agents may then be used to cure or vulcanize the ethylene acrylic elastomer by reacting with the functional group in the cure site monomer. Although the precise nature of the crosslinking agent is proprietary to the supplier of the ethylene acrylic elastomers, two main classes of curing of vulcanization agents for use with such elastomers are the class of diamines and the class of peroxides. Diamines have the advantage that they cure slower but can be used at higher temperatures without scorch from too fast a cure. Mixtures of curing agents may be used, as is known to those of skill in the art, to obtain a desirable cure rate in light of the temperature conditions of the reaction. Ethylene acrylic elastomers are commercially available, for example from DuPont under the Vamac® tradename. For example, Vamac G is used to designate a line diamine cured elastomers, while Vamac D represents a line of peroxide cured elastomers.

To make the magnetizable compositions of the invention, hard magnetic material is dispersed in a blend of an elastomeric material and a thermoplastic material prior to the onset of cure of the elastomeric material. Once the hard magnetic material is dispersed throughout both the thermoplastic phase and the uncured elastomeric phase, the elastomeric phase may be cured to provide the compositions of the invention, preferably while maintaining mixing of the two phases.

Because the elastomeric material and thermoplastic material are to be melt blended, mixing necessarily occurs above the softening or melting point of the higher melting component. Such higher melting component is usually the thermoplastic material. It may be that such a mixing temperature is above the temperature at which the curing agent reacts with the elastomeric material. If so, care must be taken to add the curing agent at a time after mixing such that both the magnetic material is dispersed into both the thermoplastic and elastomer phases on the one hand, and the elastomeric material is cured in the presence of the thermoplastic phase on the other hand. In this regard, it is preferred to use curing agents such as diamines that are not adversely affected by high temperatures such as would occur during the melt blending of a high melting thermoplastic material. With diamine curing agents, it is preferred to use crosslinking accelerators. Preferred accelerators include guanidine derivatives such as di-ortho-tolyl guanidine (DOTG).

In a preferred embodiment, magnetizable compositions of the invention are made by dynamically vulcanizing the elastomeric particles in the presence of the thermoplastic material, while continuing to mix or masticate the mixture. As noted above, the hard magnetic material may be added to either the thermoplastic material stream or the elastomer material stream or both.

A non-limiting example of a synthesis protocol that may be used to form the compositions of the invention is given in FIG. 5. FIG. 5 show diagramatically the temperature versus time for a thermoplastic stream I and an elastomeric stream II. During time range A, the two streams are individually melt blended at temperatures sufficient to soften the polymeric material. Hard magnetic material may be added at this time to stream I, to stream I, or to both as indicated at M. A cure package may be added to stream II, either with, during, or after addition of the magnetic material. Other conventional additives and processing aids may also be added to streams I and II. During time range B, the temperature of stream II is ramped up to a higher temperature before being combined with stream I. This is usually preferred to avoid thermal shock to stream II and its curing package. As shown, the temperature of stream II is brought up to that of stream I before the streams are combined. Alternatively, the two streams may be combined at different temperatures. A curing package may be added to stream II during time range B.

Whether added in time range A, time range, or both, the cure package is added to stream II at a time sufficient to permit cure of the elastomer in stream II to a significant degree after the streams are combined. The process in FIG. 5 is conveniently carried in a twin-screw extruder apparatus. In such an apparatus, the variable time corresponds roughly to the extruder path traveled by the streams. A continuous process may be developed by adjusting screw parameters, time, and temperature. Alternatively, the streams may be treated in separate mixers and combined at the times indicated in FIG. 5. In either case, it is preferred to apply mechanical energy, such as by agitating, stirring, mixing, milling, blending, etc., the combination of uncured elastomeric polymeric material, thermoplastic polymeric material, and hard magnetic material particles during the curing stage in time range C.

In a non-limiting example, a thermoplastic material is melted and stirred together with particles of a hard magnetic material. Separately, an elastomeric material is melted and optionally hard magnetic materials are added to the melted elastomeric material. In general, the thermoplastic melt is at a higher temperature than the elastomeric melt. In one embodiment, the melted stirred thermoplastic and elastomeric streams may be combined, such as in a twin screw extruder. Upon combining the thermoplastic stream and the elastomer stream, the phases continue to be mixed while a curative package is added. Conveniently, such addition can be made through a port in the twin screw extruder apparatus. Mixing is continued with the curing package for a time sufficient to partially or fully cure the elastomeric particles. In a twin screw extruder apparatus, the mixing and cure time may be conveniently adjusted by varying the length of the extruder path. The method just described will be suitable if the cure package can withstand being added to the stirred mixture at the higher temperature of the thermoplastic melt.

In another embodiment, it may be desirable to add a curative package to the elastomer stream before combining it with the thermoplastic stream. In such a case, the temperature of the elastomer stream may be ramped up at a desired rate until the curing package and elastomer mix (alternatively also including hard magnetic material particles) may be added to the thermoplastic stream with less thermal shock to the curative package. In this embodiment, it is preferred to combine the thermoplastic stream and elastomeric stream within a time after addition of the curative package to the elastomer stream that is less than the time at which the elastomer is significantly cured. As a rule of thumb, it is desired to mix the elastomer stream and thermoplastic stream within a time after addition of the curative that is less than the Ts2 of the elastomer. Ts2 is the time required, at a given temperature, for 2% cure to be completed.

In a preferred embodiment, the magnetizable compositions of the invention are incorporated into magnetic encoders, such as those used in the automotive and other industries as targets for magnetic wheel speed sensors. Encoders may be produced by a process including overmolding a composition of the invention onto a metal case that has been pretreated with adhesive. The overmolding process may be accomplished by compression molding but would preferably be accomplished in an injection molding process. Alternatively, the encoder may be produced from the compositions in a bi-material molding process, where a different thermoplastic would be molded as a structural substrate for the magnetizable compositions of the invention.

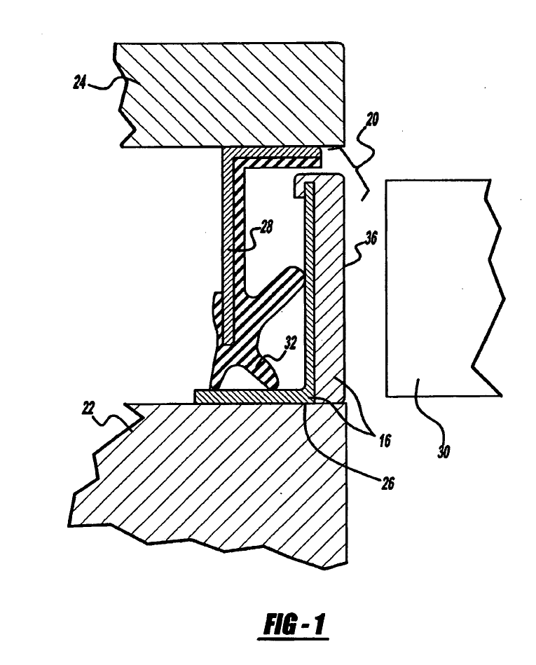

A rotational speed sensing device is illustrated in FIG. 1. A seal assembly 20 is disposed between an inner (rotating) race 22 and an outer (stationary) race 24 of a bearing assembly. The bearing assembly may be, for example, a component of a vehicle wheel bearing assembly wherein the outer race 24 is attached to a vehicle frame (not shown) or other component that it rotationally fixed relative to a vehicle frame, and the inner race 22 is rotationally affixed to a wheel. It will be appreciated that the seal assembly or encoder assembly may also be employed with other types of rotary shafts in order to sense speed and/or rotational positions of a shaft relative to a fixed body.

For purposes of illustration, the seal assembly 20 in use includes a first support member 26 (which functions as a wear sleeve and/or an encoder case) rotationally affixed to the inner race 22, and a second support member 28 (which functions as a seal case) rotationally affixed to the outer race 24. The first and second support members 26 and 28 may be made of steel, but alternatively may be made of other suitable materials, such as a thermoplastic or thermoset plastic material. As drawn in a non-limiting configuration, the stationary race 24 retains and supports a rotation sensing device 30. The rotation sensing device 30 may be for example a Hall-effect or a magneto-resistance device.

A multi-pole member 36 (also called a target wheel) is mounted or adhered to the first support member 26. It faces the rotation sensing device 30 and is spaced a predetermined distance from it. The ring member 36 is made of the magnetizable compositions described above. It functions as an encoder elastomer on the encoder case 26, forming together with the encoder case an encoder. The ring member 36 will have the magnetizable material magnetized in alternating north and south poles in the circumferential direction, which as the inner-race rotates relative to the outer race 24, move alternately past the rotation sensing device 30.

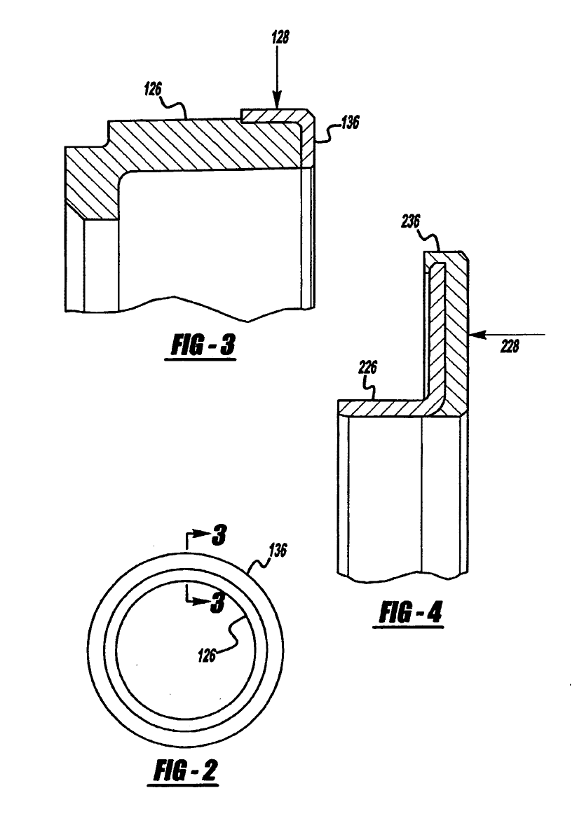

FIG. 2 shows a sensor target that includes encoder elastomer 136 on a support member 126. The elastomer 136 is preferred formed of the magnetizable compositions of the invention described above.

FIG. 3 shows a partial cross section through the line 3-3 of FIG. 2. As illustrated, the support member 126 is a powdered metal support member. The sensing position is illustrated as sensing position 128.

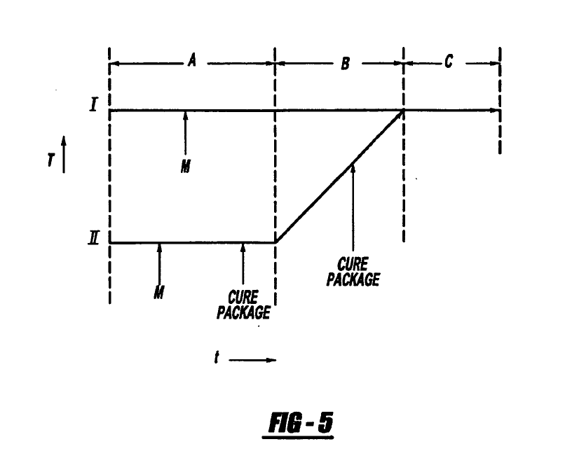

FIG. 4 shows a sensor target that includes an axial encoder elastomer 236 on a support member 226. The encoder elastomer 236 is preferably formed of the magnetizable compositions described above. As illustrated, FIG. 4 shows a stamped metal support member 226.

### EXAMPLES

Magnetizable compositions of the invention are prepared according to the recipes given in Example 1 and Example 2. The weight percents and volume percents given in Examples 1 and 2 are the percentages in the final magnetizable composition. In Examples 1 and 2, half of the ferrite material is combined with the polyester elastomer and half is combined with the ethylene acrylic elastomer in separate streams. The streams are melted and stirred together with the ferrite material. The mixing streams are combined in a twin screw extruder, followed by addition of a diamine curative package for the ethylene acrylic elastomer. After further mixing for a time sufficient to cure the Vamac G material, the magnetizable composition is removed from the twin screw extruder. The material from the extruder is combined with carbon black and optional other processing aids and molded into a disc shaped or annulus shaped ring. The disc or annulus is magnetized according to known procedures to produce an encoder elastomer for use in the invention.

| | Density | Example 1 | | Example 2 | |
|---|---|---|---|---|---|
| | g/cc | wt % | vol % | wt % | vol % |
| Polyester Elastomer | 1.115 | 14.3 | 37.4 | 13.5 | 32.1 |
| Sr-Ba Ferrite | 5.07 | 80.8 | 48.0 | 76.5 | 41.3 |
| Acrylic Elastomer | 1.03 | 5.0 | 14.6 | 10.0 | 26.6 |
| Total | | 100.0 | 100.0 | 100.0 | 100.0 |

Examples 3 and 4 give the recipes for forming magnetizable compositions of the invention using diamine curing agents and accelerators. The mixing of separate streams, heating, temperature ramping, combining, and mixing can be readily accomplished using a twin screw extruder apparatus. The ferrite and polyester elastomer are combined in a first thermoplastic stream and melt blended. In a separate stream, the acrylic elastomer, curing accelerator, and diamine curing agent are melt blended at a temperature of about 100° C. or lower. This temperature is lower than the activation temperature of the crosslinking so that no significant crosslinking occurs in the elastomeric stream. The thermoplastic stream is stirred at a temperature of about 200° C., which is sufficient to soften or melt the polyester elastomer. To avoid thermal shock to the curing agent and accelerator, the elastomer stream is ramped up in temperature prior to being combined with the thermoplastic stream at 200° C. The ramp-up speed of the temperature of the elastomeric stream is chosen such that by the time the temperature reaches 200° C. and the elastomeric stream is combined with the thermoplastic stream, the acrylic elastomer is not significantly cured or vulcanized. Once the thermoplastic stream and elastomeric stream are combined, the streams are mixed for a further period sufficient to partially or completely cure or vulcanize the acrylic elastomer. The composition is then removed, where it can be further processed on standard thermoplastic processing equipment.

In an alternative process, the strontium barium ferrite may be divided among the thermoplastic stream and elastomer stream prior to mixing the streams. Although the ferrite may be distributed between the two streams in any fashion, it is preferred that both streams contain an equal weight percent or volume percent of the ferrite. In general, it is believed that such will further enable an even distribution of ferrite particles in the thermoplastic phase and in the elastomeric phase of the magnetizable composition formed in the twin screw process.

| | | Example 3 | | | | Example 4 | | | |
|---|---|---|---|---|---|---|---|---|---|
| | Density | Charge | Charge | Wt. | Vol. | Charge | Charge | Wt. | Vol. |
| | g/cc | g | cc | % | % | g | cc | % | % |
| Polyester | 1.15 | 10.7 | 8.76 | 10.1 | 27.2 | 7.94 | 6.91 | 7.9 | 23.4 |
| Elastomer | | | | | | | | | |
| Sr-Ba Ferrite | 5.11 | 82.35 | 16.12 | 82.3 | 50.0 | 86.08 | 16.85 | 86.1 | 57.0 |
| Acrylic | 1.03 | 7.55 | 7.33 | 7.55 | 22.74 | 5.96 | 5.78 | 6.0 | 19.6 |
| Elastomer | | | | | | | | | |
| Curing | 1.10 | 0.023 | 0.021 | 0.023 | .064 | 0.018 | 0.016 | .018 | .055 |
| Accelerator | | | | | | | | | |
| Diamine | 1.28 | 0.008 | 0.006 | .008 | .018 | 0.006 | 0.005 | .006 | .016 |
| Curing Agent | | | | | | | | | |
| Total | | 100.00 | 32.23 | 100.0% | 100.0% | 100.00 | 29.55 | 100.00 | 29.55 |

1. A magnetizable composition comprising:
a first phase comprising a thermoplastic polymeric material, and
a second phase comprising a cured elastomeric polymeric material,
wherein magnetizable particles of a hard magnetic material are dispersed in the first phase and in the second phase.

2. A composition according to claim 1, wherein the elastomeric polymeric material is fully cured.

3. A composition according to claim 1, wherein the elastomeric polymeric material is partially cured.

4. A composition according to claim 1, wherein the thermoplastic polymeric material comprises a polyester thermoplastic elastomer.

5. A composition according to claim 1, wherein the elastomeric polymeric material is selected from the group consisting of acrylic elastomers and ethylene acrylic elastomers.

6. A composition according to claim 1, wherein the thermoplastic polymeric material comprises a polyester thermoplastic elastomer, the elastomeric polymeric material is selected from the group consisting of acrylic elastomers and ethylene acrylic elastomers, and the comprises 10-90% by volume of the hard magnetic material.

7. A composition according to claim 6, comprising 25-67 volume % of the hard magnetic material.

8. A composition according to claim 6, wherein the elastomeric polymeric material is present at a level of 10%-300% by weight of the thermoplastic material.

9. A composition according to claim 6, wherein the elastomeric polymeric material is present at a level of 10%-100% by weight of the thermoplastic material.

10. A composition according to claim 6, wherein the elastomeric polymeric material is present at a level of 25%-100% by weight of the thermoplastic material.

11. A shaped article comprising
a first phase comprising a thermoplastic polymeric material, and
a second phase comprising a cured elastomeric polymeric material,
wherein magnetizable particles of a hard magnetic material are dispersed in the first phase and in the second phase.

12. A shaped article according to claim 11, wherein the elastomeric polymeric material is fully cured.

13. A shaped article according to claim 11, wherein the elastomeric polymeric material is partially cured.

14. A shaped article according to claim 11, wherein the thermoplastic polymeric material comprises a polyester thermoplastic elastomer.

15. A shaped article according to claim 11, wherein the elastomeric polymeric material is selected from the group consisting of acrylic elastomers and ethylene acrylic elastomers.

16. A shaped article according to claim 11, wherein the thermoplastic polymeric material comprises a polyester thermoplastic elastomer, the elastomeric polymeric material is selected from the group consisting of acrylic elastomers and ethylene acrylic elastomers, and the comprises 10-90% by volume of the hard magnetic material.

17. A shaped article according to claim 16, comprising 25-67 volume % of the hard magnetic material.

18. A shaped article according to claim 16, wherein the elastomeric polymeric material is present at a level of 10%-300% by weight of the thermoplastic material.

19. A shaped article according to claim 16, wherein the elastomeric polymeric material is present at a level of 10%-100% by weight of the thermoplastic material.

20. A shaped article according to claim 16, wherein the elastomeric polymeric material is present at a level of 25%-100% by weight of the thermoplastic material.

21. A shaped article according to claim 11, comprising alternating opposite magnetic poles along a surface of the article.

22. A shaped article according to claim 16, comprising alternating opposite magnetic poles along a surface of the article.

23. An encoder comprising:
an encoder case; and
an encoder elastomer comprising a shaped article adhered to the case, wherein the encoder elastomer comprises:
a first phase comprising a thermoplastic polymeric material, and
a second phase comprising a cured elastomeric polymeric material,
wherein magnetizable particles of a hard magnetic material are dispersed in the first phase and in the second phase, and
wherein the encoder elastomer comprises alternating opposite magnetic poles along a surface of the article

24. A radial encoder according to claim 23.

25. An axial encoder according to claim 23.

26. An encoder according to claim 23, wherein the elastomeric polymeric material is fully cured.

27. An encoder according to claim 23, wherein the elastomeric polymeric material is partially cured.

28. An encoder according to claim 23, wherein the thermoplastic polymeric material comprises a polyester elastomer.

29. An encoder according to claim 23, wherein the elastomeric polymeric material is selected from the group consisting of acrylic clastomers and ethylene acrylic elastomers.

30. An encoder according to claim 23, wherein the thermoplastic polymeric material comprises a polyester elastomer, the elastomeric polymeric material is selected from the group consisting of acrylic elastomers and ethylene acrylic elastomers, and the composition comprises 10-90% by volume of hard magnetic material.

31. An encoder according to claim 30, wherein the composition comprises 25-67% by volume of hard magnetic material.

32. An encoder according to claim 30, wherein the elastomeric polymeric material is present at a level of 10% -300% by weight of the thermoplastic material.

33. An encoder according to claim 30, wherein the elastomeric polymeric material is present at a level of 10% -100% by weight of the thermoplastic material.

34. An encoder according to claim 30, wherein the elastomeric polymeric material is present at a level of 25% -100% by weight of the thermoplastic material.

35. A seal assembly for a bearing comprising:
an encoder adapted to be affixed to a rotating member and comprising an encoder case and an encoder elastomer adhered to the case; and
a seal disposed in sealing contact with the encoder and adapted to be affixed to a stationary member;
wherein the encoder elastomer comprises:
a first phase comprising a thermoplastic polymeric material, and
a second phase comprising a cured elastomeric polymeric material,
wherein magnetizable particles of a hard magnetic material are dispersed in the first phase and in the second phase.

36. A seal assembly according to claim 35, wherein the elastomeric polymeric material is selected from the group consisting of acrylic elastomers and ethylene acrylic elastomers.

37. A seal assembly according to claim 35, wherein the thermoplastic polymeric material comprises a polyester thermoplastic elastomer, the elastomeric polymeric material is selected from the group consisting of acrylic elastomers and ethylene acrylic elastomers, and the comprises 10-90% by volume of the hard magnetic material.

38. A seal assembly according to claim 37, comprising 25-67 volume % of the hard magnetic material.

39. A seal assembly according to claim 37, wherein the elastomeric polymeric material is present at a level of 10%-300% by weight of the thermoplastic material.

40. A seal assembly according to claim 35, wherein the encoder is a radial encoder.

41. A seal assembly according to claim 35, wherein the encoder is an axial encoder.

42. A method of determining the rotational speed of a rotating member, comprising sensing a magnetic field in a target comprising a magnetizable substance and affixed to the rotating member, wherein the magnetizable substance comprises:
a first phase comprising a thermoplastic polymeric material, and
a second phase comprising a cured elastomeric polymeric material,
wherein magnetizable particles of a hard magnetic material are dispersed in the first phase and in the second phase.

43. A method according to claim 42, wherein the elastomeric polymeric material is selected from the group consisting of acrylic elastomers and ethylene acrylic elastomers.

44. A method according to claim 42, wherein the thermoplastic polymeric material comprises a polyester thermoplastic elastomer, the elastomeric polymeric material is selected from the group consisting of acrylic elastomers and ethylene acrylic elastomers, and the magnetizable substance comprises 10-90% by volume of the hard magnetic material.

45. A method according to claim 42, wherein the magnetizable substance comprises 25-67 % by volume of the hard magnetic material.

46. A seal assembly according to claim 44, wherein the elastomeric polymeric material is present at a level of 10%-300% by weight of the thermoplastic material.

47. A process for making a magnetizable polymer composition comprising:
dispersing a hard magnetic material in a blend of a thermoplastic material and an elastomeric material, wherein the elastomeric material is in an uncured state or a partially cured state; and
curing the elastomeric material in the presence of the thermoplastic material and the hard magnetic material.

48. A process according to claim 47, comprising:
combining a thermoplastic polymeric material, an uncured elastomeric polymeric material, and particles of a hard magnetic material to form a combination, wherein the combination comprises 10-90% by volume of the hard magnetic material;
applying mechanical energy to the combination to form a mixture; and
curing the elastomeric material while continuing to apply mechanical energy.

49. A process according to claim 47, comprising dynamically vulcanizing the elastomeric material in the presence of the thermoplastic material and the hard magnetic material.

50. A process according to claim 47, carried out in a twin screw extrusion apparatus.

51. A process according to claim 47, wherein the magnetizable polymer composition comprises 10-90 % by volume of the hard magnetic material.

52. A process according to claim 51, wherein the composition comprises 10 to 300 parts of the elastomeric material per 100 parts of thermoplastic material.

53. A process according to claim 52, wherein the thermoplastic material comprises a thermoplastic elastomer.

54. A process according to claim 52, wherein the elastomeric material is selected from the group consisting of acrylic elastomers and ethylene acrylic elastomers.

55. A process according to claim 54, wherein the composition comprises 10 to 100 parts of the elastomeric material per 100 parts of thermoplastic material.

56. A process according to claim 54, wherein the composition comprises 25 to 100 parts of the elastomeric material per 100 parts of thermoplastic material.
